(19) United States
(12) Patent Application Publication
(10) Pub. No.: US 2023/0369394 A1
(43) Pub. Date: Nov. 16, 2023

(54) SELF-ALIGNED DIELECTRIC ISOLATION STRUCTURE FOR NANOSHEET

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Andrew M. Greene, Slingerlands, NY (US); Junli Wang, Slingerlands, NY (US); Nicolas Jean Loubet, GUILDERLAND, NY (US)

(21) Appl. No.: 17/662,851

(22) Filed: May 11, 2022

(51) Int. Cl. H01L 29/06; H01L 29/66; H01L 29/786; H01L 29/78

(52) U.S. Cl. CPC H01L 29/0673; H01L 29/66545; H01L 29/78696; H01L 29/785; H01L 29/42392

(57) ABSTRACT

Embodiments of present invention provide a method of forming a nanosheet transistor structure. The method includes forming a nanosheet stack on a substrate, the nanosheet stack having a set of nanosheets separated by a set of sacrificial sheets; forming a vertical dielectric pillar separated from the nanosheet stack; forming a dielectric liner lining the nanosheet stack and the vertical dielectric pillar; forming a set of inner spacers between the set of nanosheets; forming a side spacer between the set of inner spacers and the vertical dielectric pillar, the side spacer being surrounded by the dielectric liner at least at a left side between the set of inner spacers and the side spacer and at a right side between the side spacer and the vertical dielectric pillar; and forming a replacement gate stack surrounding the set of nanosheets. A structure formed thereby is also provided.

### BACKGROUND

The present application relates to manufacturing of semiconductor integrated circuits. More particularly, it relates to a method of forming a nanosheet transistor structure with self-aligned dielectric isolation.

As semiconductor industry moves towards smaller node, for example 7-nm node and beyond, field-effect-transistors (FETs) are aggressively scaled in order to fit into the reduced footprint or real estate, as defined by the node, with increased device density. Among various types of FETs, non-planar FETs such as nanosheet FETs, and its variance of nanowire FETs, are particularly suited to meet this continued device scaling needs.

A nanosheet FET generally has a channel region that includes one or more elongated semiconductor layers in a stacked configuration, wherein each such semiconductor layer is known as a nanosheet layer (or nanosheet channel) and has a width that in general is substantially greater than a thickness of the nanosheet layer.

In forming nanosheet transistors, a replacement gate stack, including gate dielectric and one or more layers of work-function metals, is generally formed in between the stacked nanosheets to fully surround the nanosheets thereby forming a gate-all-around (GAA) transistor structure. The replacement gate stack is usually formed from a space at the side of the stacked nanosheet stack into spaces between the stacked nanosheets, which requires the space at the side of the nanosheets being larger than the spaces between the nanosheets such that no pinch off happens before the spaces between the nanosheets are fully filled with the replacement gate stack.

On the other hand, during a process of forming inner spacers at the end of nanosheets, if the space at the side of the nanosheets is larger than the spaces between the nanosheets, particularly at near the end of the nanosheets where inner spacers are to be formed, voids may be formed in areas surrounding the inner spacers. Such voids may cause electric leakage of source/drain that are subsequently formed over the inner spacers.

### SUMMARY

Embodiments of present invention provide a method of forming a nanosheet transistor structure. The method includes forming a nanosheet stack on a substrate, the nanosheet stack having a set of nanosheets separated by a set of sacrificial sheets; forming a vertical dielectric pillar separated from the nanosheet stack; forming a dielectric liner lining the nanosheet stack and the vertical dielectric pillar; forming a set of inner spacers between the set of nanosheets; forming a side spacer between the set of inner spacers and the vertical dielectric pillar, the side spacer being surrounded by the dielectric liner at least at a left side between the set of inner spacers and the side spacer and at a right side between the side spacer and the vertical dielectric pillar; and forming a replacement gate stack surrounding the set of nanosheets.

In one embodiment, the side spacer has a horizontal thickness b2 that is equal to or smaller than a distance d1 between any two of the set of nanosheets. In another embodiment, a distance b1 between the nanosheet stack and the vertical dielectric pillar is larger than the distance d1 between any two of the set of nanosheets. In yet another embodiment, the distance b1 between the nanosheet stack and the vertical dielectric pillar is equal to the horizontal thickness b2 of the side spacer plus two-times the thickness a1 of the dielectric liner. In other words, b1=b2+2*a1.

Embodiments of present invention also provide a nanosheet transistor structure formed by the method described above.

### BRIEF DESCRIPTION OF THE DRAWINGS

The present invention will be understood and appreciated more fully from the following detailed description of embodiments of present invention, taken in conjunction with accompanying drawings of which:

FIGS. 1-5 are demonstrative illustrations of cross-sectional views of a nanosheet transistor structure during a process of manufacturing thereof according to embodiments of present invention;

FIGS. 6A-6D to FIGS. 14A-14D are demonstrative illustrations of various cross-sectional views of a nanosheet transistor structure during a process of manufacturing thereof according to embodiments of present invention; and

FIG. 15 is a demonstrative illustration of a flow-chart of a method of manufacturing a nanosheet transistor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, the same or similar reference numbers are used throughout the drawings to denote the same or similar features, elements, or structures, and thus, a detailed explanation of the same or similar features, elements, or structures may not be repeated for each of the drawings for economy of description.

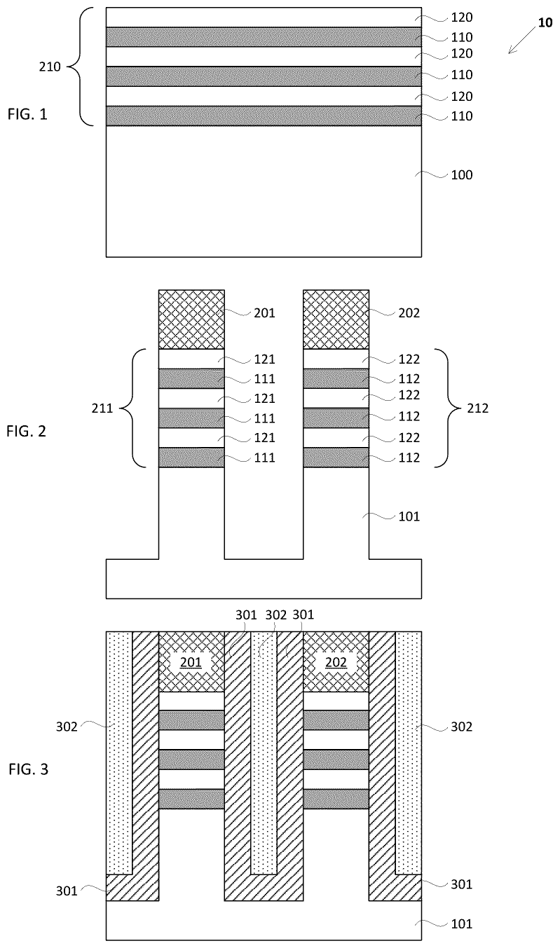

FIG. 1 is a demonstrative illustration of cross-sectional view of a nanosheet transistor structure during a process of manufacturing thereof according to embodiments of present invention. More specifically, FIG. 1 illustrates an initial structure 10 of the nanosheet transistor structure having a semiconductor substrate 100, a set of nanosheets 120, and a set of sacrificial sheets 110. More specifically, the set of nanosheets 120 are stacked together with the set of sacrificial sheets 110 in an alternating fashion, one over another as being illustrated in FIG. 1, forming a nanosheet stack 210 on top of the substrate 100. The set of nanosheets 120 may each have a thickness around, for example, 4 nm to 12 nm, and the set of sacrificial sheets 110 may each have a thickness around 6 nm to 20 nm. In one embodiment, the set of nanosheets 120 may be made of silicon (Si) and the set of sacrificial sheets 110 may be made of silicon-germanium (SiGe) with a predetermined Ge concentration level. In another embodiment, the set of nanosheets 120 may be made of SiGe with a first Ge concentration level, and the set of sacrificial sheets 110 may be made of SiGe as well but with a second Ge concentration level. Other types of different materials may be used as well. The difference in Ge concentration levels between the set of nanosheets 120 and the set of sacrificial sheets 110 may result in different etch selectivity, which may facilitate the formation of the nanosheet transistor structure as being described below in more details. The substrate 100 may be a bulk semiconductor substrate such as a Si substrate, a SiGe substrate, or a silicon-on-insulator (SOI) substrate.

FIG. 2 is a demonstrative illustration of cross-sectional view of a nanosheet transistor structure during a process of manufacturing thereof, following the step illustrated in FIG. 1, according to embodiments of present invention. More specifically, embodiments of present invention provide forming a first nanosheet stack 211 and a second nanosheet stack 212 from the nanosheet stack 210 illustrated in FIG. 1. For example, using a lithographic patterning process, hard masks 201 and 202 may be formed on top of the nanosheet stack 210. The nanosheet stack 210 may subsequently be etched such as using a reactive-ion-etching (RIE) process to form the first nanosheet stack 211 and the second nanosheet stack 212. More particularly, the first nanosheet stack 211 may include a first set of nanosheets 121 separated by a first set of sacrificial sheets 111, and the second nanosheet stack 212 may include a second set of nanosheets 122 separated by a second set of sacrificial sheets 112. The etching may be performed deep into the substrate 100 to create a substrate 101.

FIG. 3 is a demonstrative illustration of cross-sectional view of a nanosheet transistor structure during a process of manufacturing thereof, following the step illustrated in FIG. 2, according to embodiments of present invention. More specifically, embodiments of present invention provide forming an insulating liner 301 on top of the first and second nanosheet stacks 211 and 212. More specifically, the insulating liner 301 may be a conformal liner and may be deposited to line sidewalls of the first and second nanosheet stacks 211 and 212 and top of the substrate 101. The insulating liner 301 may have a thickness that is less than half of a space between the first nanosheet stack 211 and the second nanosheet stack 212. A thickness like this results in a gap formed by the insulating liner 301 between the first nanosheet stack 211 and the second nanosheet stack 212. Embodiments of present invention then provide depositing a layer of dielectric material such as, for example, silicon-nitride (SiN) or other types of materials into the gap to form a vertical dielectric pillar 302 between the first and second nanosheet stacks 211 and 212. By the way of its formation, the vertical dielectric pillar 302 may be separated from the first nanosheet stack 211, and from the second nanosheet stack 212, by the thickness of the insulating liner 301.

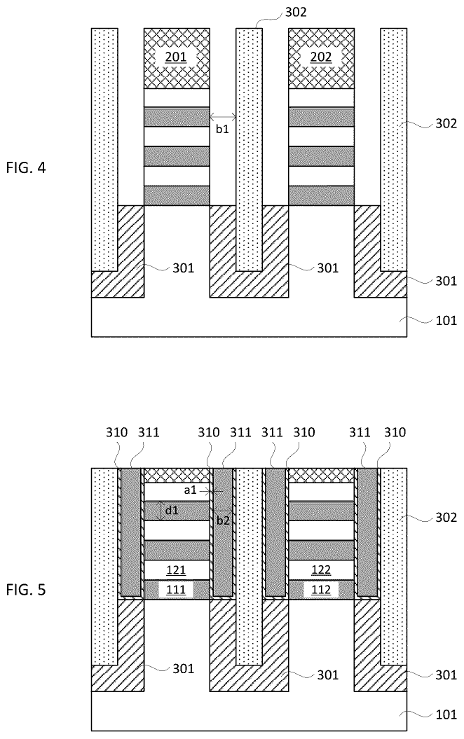

FIG. 4 is a demonstrative illustration of cross-sectional view of a nanosheet transistor structure during a process of manufacturing thereof, following the step illustrated in FIG. 3, according to embodiments of present invention. More specifically, embodiments of present invention provide recessing the insulating liner 301 to create openings between the vertical dielectric pillar 302 and the first and second nanosheet stacks 211 and 212. The openings may have a width, for example between the set of nanosheets 121 (or the set of sacrificial sheets 111) and the vertical dielectric pillar 302, that is the same as the thickness of the insulating liner 301. The openings expose sidewalls of the first and second nanosheet stacks 211 and 212 and that of the vertical dielectric pillar 302. The recessing of the insulating liner 301 may be made until the bottom most sacrificial sheets 111 and 112 are exposed. In the meantime, the recessing may also leave sufficient amount of the insulating liner 301 in the substrate 101 below the level of the first and second nanosheet stacks 211 and 212, which helps prevent over-etch of work-function metals during a process of forming PFET and NFET work-function metals.

FIG. 5 is a demonstrative illustration of cross-sectional view of a nanosheet transistor structure during a process of manufacturing thereof, following the step illustrated in FIG. 4, according to embodiments of present invention. More specifically, embodiments of present invention provide lining the openings between the vertical dielectric pillar 302 and the first and second nanosheet stacks 211 and 212 with a dielectric liner 310 and subsequently filling any remaining openings with a layer 311 of sacrificial material. The dielectric liner 310 may be a conformal liner to have a thickness a1 and may be used to adjust, such as narrow the openings between the vertical dielectric pillar 302 and the first and second nanosheet stacks 211 and 212 such that the remaining opening may have a width that is equal to or smaller than a distance d1 between any two neighboring nanosheets of the first set of nanosheets 121 of the first nanosheet stack 211.

Embodiments of present invention then provide filling the remaining openings between the dielectric liner 310 with the layer 311 of sacrificial material such as, for example, amorphous silicon-germanium (a-SiGe). However, embodiments of present invention are not limited in this aspect and other types of materials may be used as well to fill the remaining openings between the first nanosheet stack 211 and the vertical dielectric pillar 302. Preferably, the layer 311 of sacrificial material may have a same or similar etch selectivity to that of the first set of sacrificial sheets 111 to facilitate a later process of forming inner spacers. The layer 311 of sacrificial material may have a horizontal thickness b2 that is equal to or smaller than distance d1 between any two neighboring nanosheets of the first set of nanosheets 121 of the first nanosheet stack 211. After the deposition of the layer 311 of sacrificial material, the structure may be planarized through, for example, a chemical-mechanic-polishing (CMP) process.

In the above, for the ease of description without loss of generality, reference is made to the first nanosheet stack 211 and the first set of nanosheets 121 and the first set of sacrificial sheets 111 of the first nanosheet stack 211. However, a person skilled in the art will appreciate that similar description may be applied to the second nanosheet stack 212 and the second set of nanosheets 122 and the second set of sacrificial sheets 112 of the second nanosheet stack 212.

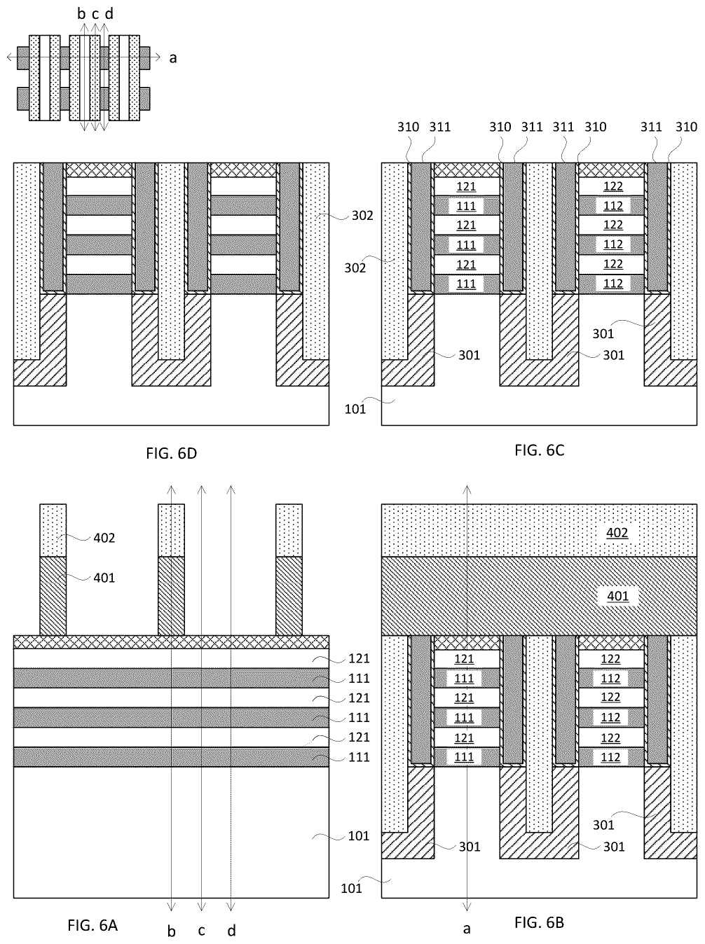

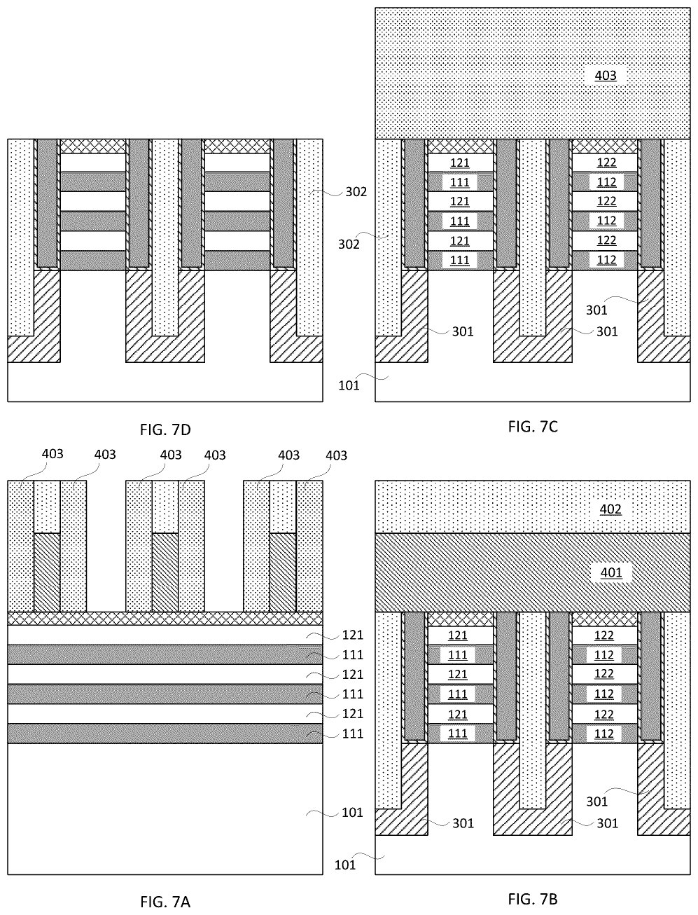

FIGS. 6A, 6B, 6C, and 6D are demonstrative illustrations of various cross-sectional views of the nanosheet transistor structure during a process of manufacturing thereof, following the step illustrated in FIG. 5, according to embodiments of present invention. More specifically, with reference to a simplified layout view of the structure at the upper-left corner, FIG. 6A illustrates a cross-sectional view of the structure along an arrowed line-a across gates along the nanosheets; FIG. 6B illustrates a cross-sectional view of the structure along an arrowed line-b at and along the gates across the nanosheets; FIG. 6C illustrates a cross-sectional view of the structure along an arrowed line-c at and along a sidewall spacer of the gates across the nanosheets; and FIG. 6D illustrates a cross-sectional view of the structure along an arrowed line-d at a source/drain region across the nanosheets. Locations of the arrowed line-a, line-b, line-c, and line-d are also illustratively shown in FIG. 6A and FIG. 6B. In the following drawings from FIGS. 7A-7D to FIGS. 14A-14D, cross-sectional reviews of the structure at various manufacturing stages are provided in a manner like FIGS. 6A-6D, and thus similar description to these drawings will not be repeated.

More specifically, embodiments of present invention provide forming dummy gates on top of the first and second nanosheet stacks 211 and 212. More specifically, a layer of dummy gate material may be formed, for example deposited, on top of the first and second nanosheet stacks 211 and 212. A hard mask 402 may be subsequently formed through a lithographic patterning process on top of the layer of dummy gate material. Gate patterns may then be transferred, through for example a reactive-ion-etching (RIE) process, from the hard mask 402 to the layer of dummy gate material underneath thereof, thereby forming the dummy gates 401.

FIGS. 7A, 7B, 7C, and 7D are demonstrative illustrations of various cross-sectional views of the nanosheet transistor structure during a process of manufacturing thereof, following the step illustrated in FIGS. 6A, 6B, 6C, and 6D, according to embodiments of present invention. More specifically, embodiments of present invention provide forming sidewall spacers 403 against sidewalls of the dummy gate 401 and the hard mask 402 at the top thereof. The sidewall spacers 403 may be seen in FIG. 7A and FIG. 7C, the latter illustrates a cross-sectional view of the structure along the sidewall spacer 403 of the dummy gates 401. The sidewall spacers 403 may be made of silicon-nitride (SiN), silicon-oxide-carbon (SiOC), silicon-oxycarbonitride (SiOCN), silicon-borocarbonitride (SiBCN) or any other suitable dielectric material.

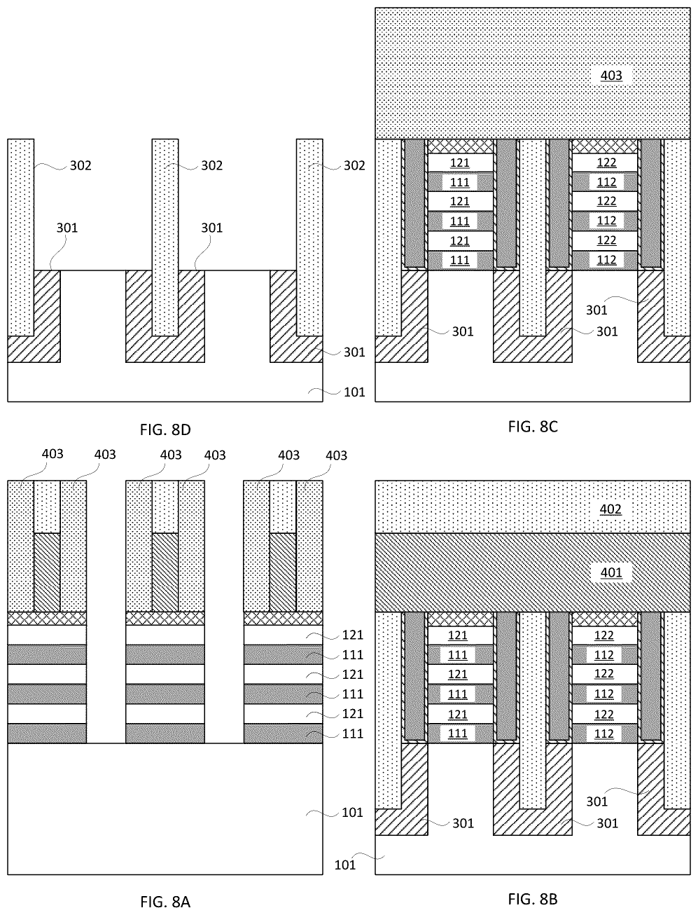

FIGS. 8A, 8B, 8C, and 8D are demonstrative illustrations of various cross-sectional views of the nanosheet transistor structure during a process of manufacturing thereof, following the step illustrated in FIGS. 7A, 7B, 7C, and 7D, according to embodiments of present invention. More specifically, embodiments of present invention provide performing etching of the first nanosheet stack 211 using the sidewall spacers 403 as masks to create openings for forming source/drain regions of the nanosheet transistor structure. As is illustrated in FIGS. 8A and 8C, portions of the first set of nanosheets 121 and portions of the first set of sacrificial sheets 111 between the two neighboring sidewall spacers 403 may be removed to expose the underneath substrate 101. Similar description may be applied to a process being applied to the second nanosheet stack 212. However, for the sake of presenting essence of present invention with clarity without getting lost in redundance, descriptions of processes being applied to the second nanosheet stack 212, which are significantly similar to that being applied to the first nanosheet stack 211, will be omitted hereinafter.

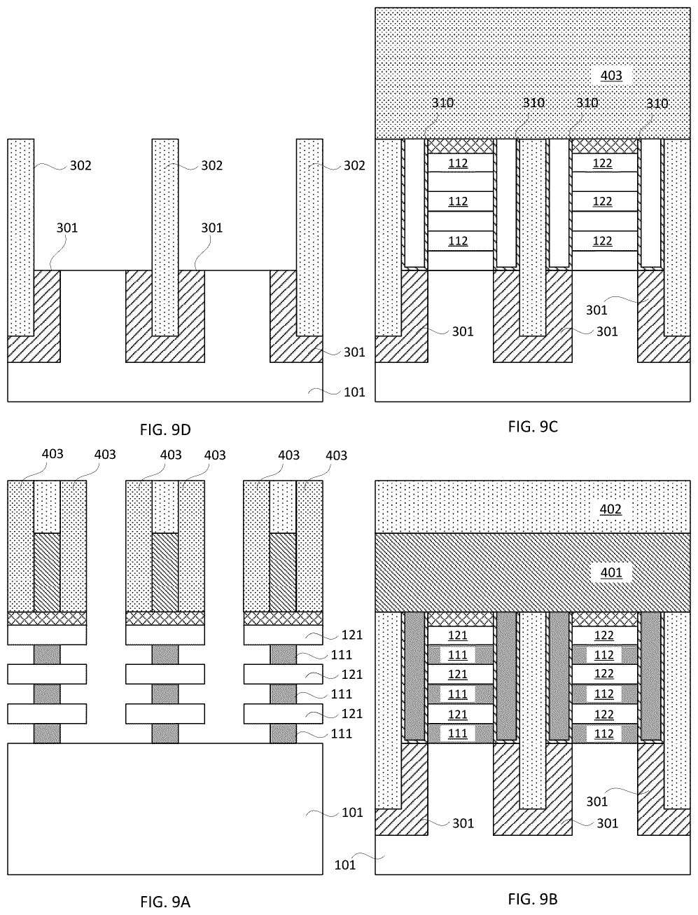

FIGS. 9A, 9B, 9C, and 9D are demonstrative illustrations of various cross-sectional views of the nanosheet transistor structure during a process of manufacturing thereof, following the step illustrated in FIGS. 8A, 8B, 8C, and 8D, according to embodiments of present invention. More specifically, embodiments of present invention provide performing indentation of the first set of sacrificial sheets 111 that separate the first set of nanosheets 121. The indentation removes a portion of the set of sacrificial sheets 111 at an end thereof, between the neighboring nanosheets 121, creating spaces for forming inner spacers as being described below in more details. The indention also removes a portion of the layer 311 of sacrificial material between the vertical dielectric pillar 302 and the first nanosheet stack 211, at a region next to an end region of the first nanosheet stack 211.

The indentation may be performed through a selective etching process. The selective etching process may remove or etch away the portion of the first set of sacrificial sheets 111 and the portion of the layer 311 of sacrificial material, selective to the set of nanosheets 121 and the dielectric liner 301. In other words, the set of nanosheets 121 and the dielectric liner 301 remain largely intact, not being etched, and not being affected. The portions being removed may be near an end region of the first nanosheet stack 211. As being illustrated in FIGS. 9A and 9C, the portions being removed, both the sacrificial sheets 111 and the layer 311 of sacrificial material, are in regions underneath the sidewall spacers 403.

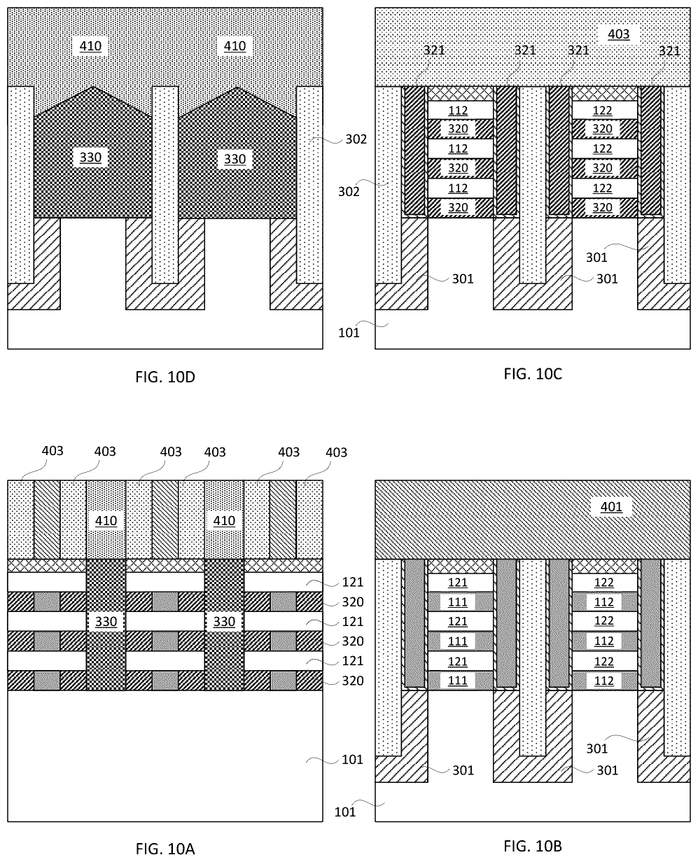

FIGS. 10A, 10B, 10C, and 10D are demonstrative illustrations of various cross-sectional views of the nanosheet transistor structure during a process of manufacturing thereof, following the step illustrated in FIGS. 9A, 9B, 9C, and 9D, according to embodiments of present invention. More specifically, embodiments of present invention provide forming inner spacers 320 through, for example, a conformal deposition process as being illustrated in FIG. 10A and 10C and forming side spacers 321 between the vertical dielectric pillar 302 and the first nanosheet stack 211 near an end region of the first nanosheet stack 211. The side spacers 321 may have a horizontal thickness of b2 that is smaller than distance b1, as a person skilled in the art will appreciate from FIG. 5. In other words, distance b1, thickness a1 and horizontal thickness b2 may satisfy the following relationship b1=b2+2*a1.

Embodiments of present invention further provide forming source/drain regions 330 through epitaxial growth of silicon (Si) or silicon-germanium (SiGe) materials next to the set of nanosheets 121. An interlevel-dielectric layer (ILD) material 410 may be subsequently deposited on top of the source/drain regions 330 between the sidewall spacers 403. A chemical-mechanic-polishing (CMP) process may be subsequently used to planarize a top surface above the gate structures for further processing.

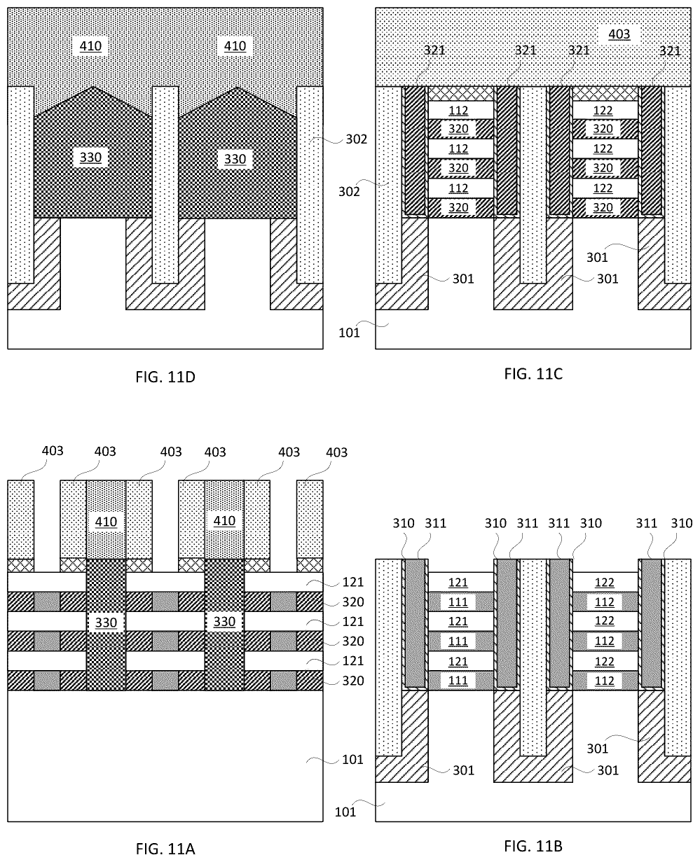

FIGS. 11A, 11B, 11C, and 11D are demonstrative illustrations of various cross-sectional views of the nanosheet transistor structure during a process of manufacturing thereof, following the step illustrated in FIGS. 10A, 10B, 10C, and 10D, according to embodiments of present invention. More specifically, embodiments of present invention provide removing the dummy gates 401 between the sidewall spacers 403 and the hard mask 201 underneath the dummy gates 401, exposing the nanosheet stack 211 for a subsequent replacement-metal-gate (RMG) process.

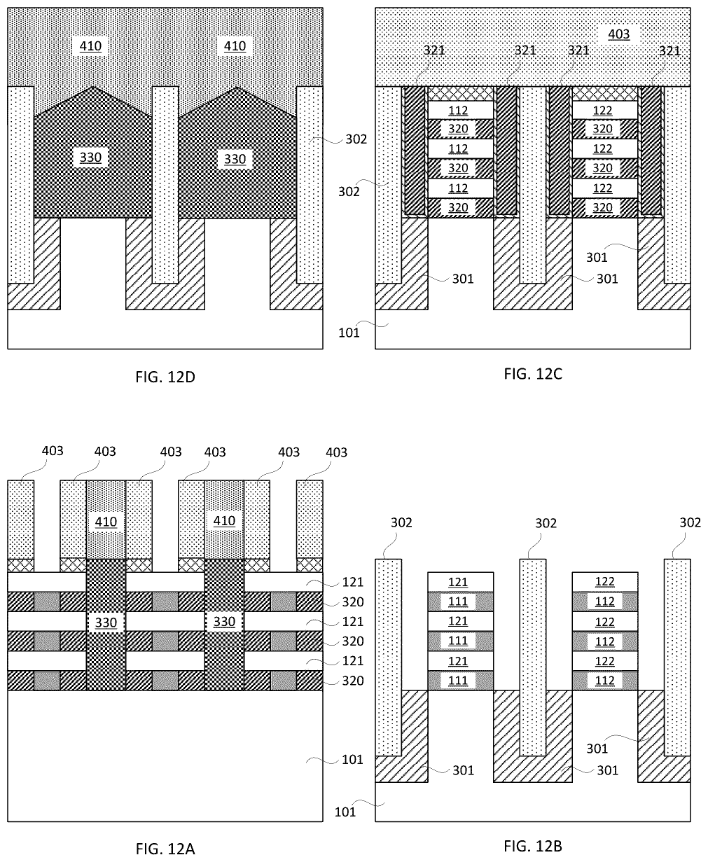

FIGS. 12A, 12B, 12C, and 12D are demonstrative illustrations of various cross-sectional views of the nanosheet transistor structure during a process of manufacturing thereof, following the step illustrated in FIGS. 11A, 11B, 11C, and 11D, according to embodiments of present invention. More specifically, embodiments of present invention provide removing the sacrificial material, such as amorphous SiGe, of the layer 311 between the first nanosheet stack 211 and the vertical dielectric pillar 302. Embodiments of present invention also provide removing the dielectric liner 310 that line the vertical dielectric pillar 302 and the sidewalls of the first nanosheet stack 211.

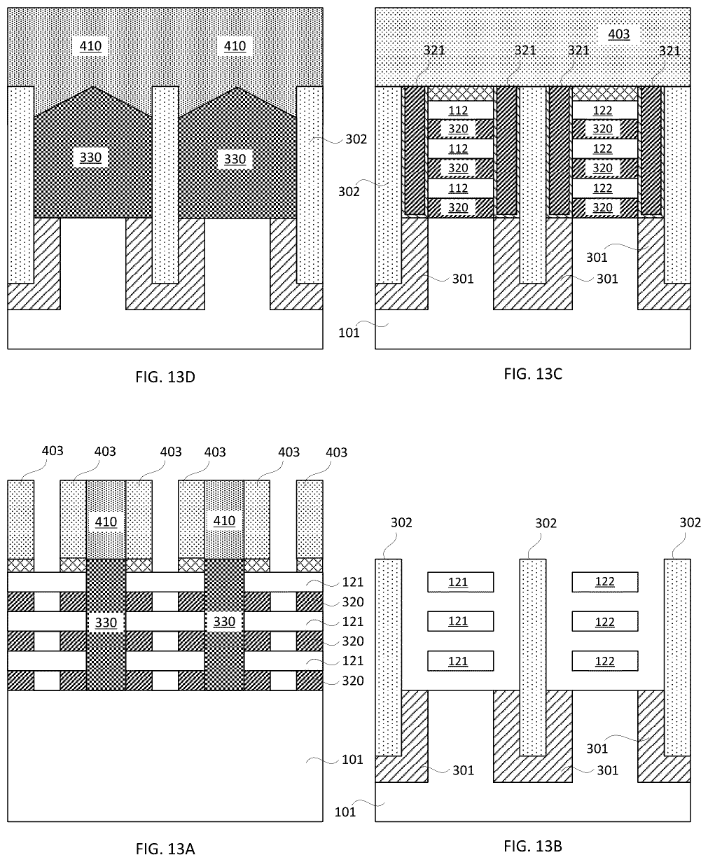

FIGS. 13A, 13B, 13C, and 13D are demonstrative illustrations of various cross-sectional views of the nanosheet transistor structure during a process of manufacturing thereof, following the step illustrated in FIGS. 12A, 12B, 12C, and 12D, according to embodiments of present invention. More specifically, embodiments of present invention further provide removing, selectively, the sacrificial sheets 111 between the set of nanosheets 121 thereby creating cavities or openings surrounding a central portion of the set of nanosheets 121.

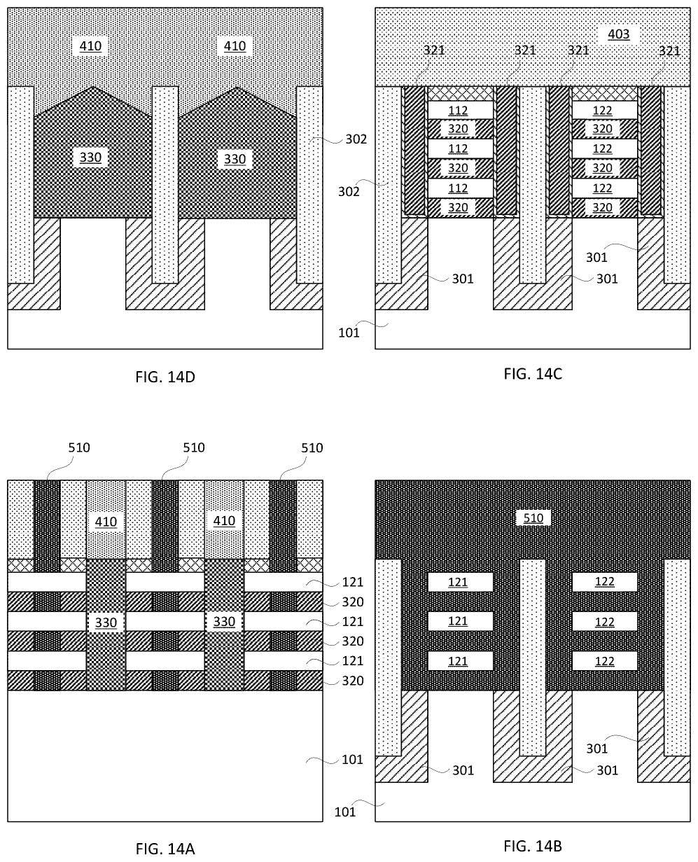

FIGS. 14A, 14B, 14C, and 14D are demonstrative illustrations of various cross-sectional views of the nanosheet transistor structure during a process of manufacturing thereof, following the step illustrated in FIGS. 13A, 13B, 13C, and 13D, according to embodiments of present invention. More specifically, embodiments of present invention provide forming a replacement gate stack 510 including depositing a gate dielectric, one or more layers of work-function metals to surround the set of nanosheets 121, and a gate metal to finish forming metal gate of the transistor.

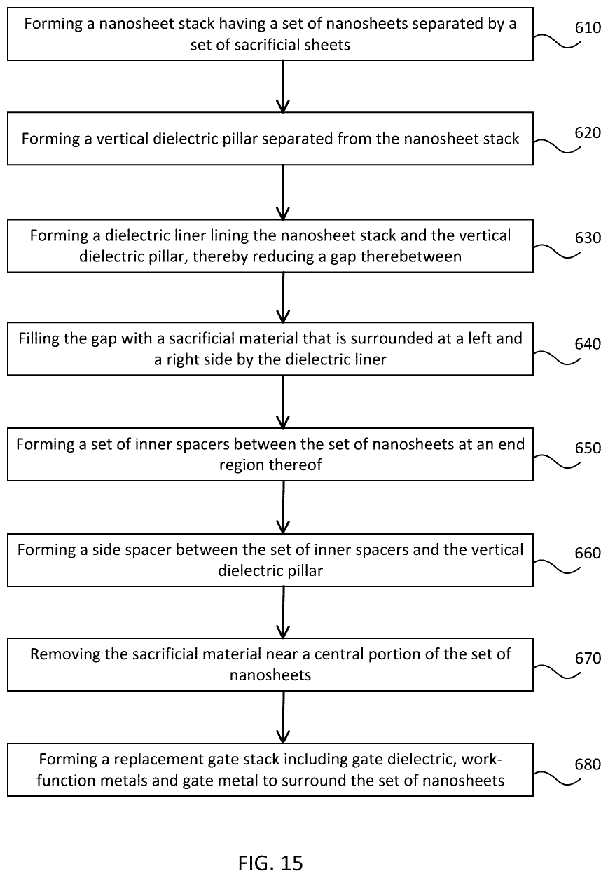

FIG. 15 is a demonstrative illustration of a flow-chart of a method of manufacturing a nanosheet transistor structure according to embodiments of present invention. More particularly, embodiments of present invention provide (610) forming a nanosheet stack having a set of nanosheets separated by a set of sacrificial sheets; (620) forming a vertical dielectric pillar that is separated from the nanosheet stack by a gap with the gap being larger than a thickness of the sacrificial sheets separating the nanosheets; (630) forming a dielectric liner lining the nanosheet stack and the vertical dielectric pillar, thereby reducing the gap between the nanosheet stack and the vertical dielectric pillar to be equal to or smaller than the thickness of the sacrificial sheets; (640) filling the gap with a sacrificial material, resulting the sacrificial material being surrounded at least at a left side and a right side by the dielectric liner; (650) forming a set of inner spacers between the set of nanosheets at an end region of the set of nanosheets; (660) forming a side spacer that situates between the set of inner spacers and the vertical dielectric pillar; (670) removing the sacrificial material near a central portion of the set of nanosheets; and (680) forming a replacement gate stack including a gate dielectric, one or more layers of work-function metals, and a gate metal surrounding the set of nanosheets to form the nanosheet transistor structure.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A nanosheet transistor structure comprising:
a nanosheet stack separated from a vertical dielectric pillar, the nanosheet stack having a set of nanosheets;
a set of inner spacers between the set of nanosheets;
a side spacer between the set of inner spacers and the vertical dielectric pillar; and
a dielectric liner surrounding the side spacer at least at a left side between the set of inner spacers and the side spacer and at a right side between the side spacer and the vertical dielectric pillar.

2. The nanosheet transistor structure of claim 1, wherein the side spacer has a horizontal thickness b2 that is equal to or smaller than a distance d1 between any two of the set of nanosheets.

3. The nanosheet transistor structure of claim 1, wherein a distance b1 between the nanosheet stack and the vertical dielectric pillar is larger than a distance d1 between any two of the set of nanosheets.

4. The nanosheet transistor structure of claim 1, wherein a distance b1 between the nanosheet stack and the vertical dielectric pillar is equal to a horizontal thickness b2 of the side spacer plus two-times a thickness a1 of the dielectric liner, that is, b1=b2+2*a1.

5. The nanosheet transistor structure of claim 1, wherein the dielectric liner has a thickness a1 of at least 1 nm.

6. A method of forming a nanosheet transistor structure comprising:
forming a nanosheet stack on a substrate, the nanosheet stack having a set of nanosheets separated by a set of sacrificial sheets;
forming a vertical dielectric pillar separated from the nanosheet stack;
forming a dielectric liner lining the nanosheet stack and the vertical dielectric pillar;
forming a set of inner spacers between the set of nanosheets;
forming a side spacer between the set of inner spacers and the vertical dielectric pillar, the side spacer being surrounded by the dielectric liner at least at a left side between the set of inner spacers and the side spacer and at a right side between the side spacer and the vertical dielectric pillar; and
forming a replacement gate stack surrounding the set of nanosheets.

7. The method of claim 6, wherein the side spacer has a horizontal thickness b2 that is equal to or smaller than a distance d1 between any two neighboring nanosheets of the set of nanosheets.

8. The method of claim 6, wherein a distance b1 between the nanosheet stack and the vertical dielectric pillar is larger than a distance d1 between any two neighboring nanosheets of the set of nanosheets.

9. The method of claim 6, wherein the nanosheet stack is a first nanosheet stack; the set of nanosheets is a first set of nanosheets; and the set of sacrificial sheets is a first set of sacrificial sheets, further comprising:
forming a second nanosheet stack, the second nanosheet stack having a second set of nanosheets separated by a second set of sacrificial sheets, the second nanosheet stack being separated from the first nanosheet stack; and
forming an insulating liner lining the first and the second nanosheet stack; the insulating liner being conformal to have a thickness that is equal to a distance b1 between the first nanosheet stack and the vertical dielectric pillar.

10. The method of claim 9, wherein forming the vertical dielectric pillar comprising forming the vertical dielectric pillar in a gap, between the first and the second nanosheet stack, formed by the insulating liner.

11. The method of claim 10, further comprising:
recessing the insulating liner to create an opening between the nanosheet stack and the vertical dielectric pillar; and
filling the opening with a layer of sacrificial material, the layer of sacrificial material being surrounded at least at a left and a right side by the dielectric liner.

12. The method of claim 11, wherein forming the replacement gate stack comprises:
removing the layer of sacrificial material;
removing the dielectric liner lining the nanosheet stack and the vertical dielectric layer;
removing the set of sacrificial sheets between the set of nanosheets; and
depositing the replacement gate stack to surround the set of nanosheets.

13. A method of forming a nanosheet transistor structure, the method comprising:
forming a first nanosheet stack having a first set of nanosheets, the nanosheets being separated by a distance d1;
forming a vertical dielectric pillar separated horizontally from the first nanosheet stack by a distance b1;
forming a dielectric liner of a thickness a1 lining the first nanosheet stack and the vertical dielectric pillar;
forming a set of inner spacers between the first set of nanosheets;
forming a side spacer of a horizontal thickness b2 between the set of inner spacers and the vertical dielectric pillar; and
forming a replacement gate stack surrounding the first set of nanosheets.

14. The method of claim 13, wherein the horizontal thickness b2 of the side spacer is equal to or smaller than the distance d1 separating the nanosheets.

15. The method of claim 13, wherein the distance b1 between the nanosheet stack and the vertical dielectric pillar is larger than the distance d1 separating the nanosheets.

16. The method of claim 13, wherein the distance b1 between the nanosheet stack and the vertical dielectric pillar is equal to the horizontal thickness b2 of the side spacer plus two-times the thickness a1 of the dielectric liner, that is, b1=b2+2*a1.

17. The method of claim 13, wherein the first set of nanosheets are separated by a first set of sacrificial sheets, further comprising depositing a layer of sacrificial material on top of the dielectric liner between the first nanosheet stack and the vertical dielectric pillar, before forming the set of inner spacers, wherein the layer of sacrificial material has an etch selectivity similar to that of the first set of sacrificial sheets.

18. The method of claim 17, further comprising, after forming the inner spacers and the side spacer, selectively removing the layer of sacrificial material and the dielectric liner underneath thereof between the first nanosheet stack and the vertical dielectric pillar and selectively removing the first set of sacrificial sheets to expose a central portion of the first set of nanosheets for forming the replacement gate stack.

19. The method of claim 13, wherein forming the vertical dielectric pillar comprises forming an insulating liner lining the first nanosheet stack and a second nanosheet stack neighboring the first nanosheet stack and forming the vertical dielectric pillar in a gap formed by the insulating liner between the first and second nanosheet stacks.

20. The method of claim 19, further comprising recessing the insulating liner below the first nanosheet stack to expose sidewalls of the first nanosheet stack and the vertical dielectric pillar.
